(19) United States
(12) Patent Application Publication
(10) Pub. No.: US 2004/0101070 A1
(43) Pub. Date: May 27, 2004

(54) Receiver apparatus quantitatively evaluating errors

(76) Inventor: Kiyohiko Yamazaki, Kanagawa (JP)

Correspondence Address: RABIN & Berdo, PC, 1101 14TH STREET, NW, SUITE 500, WASHINGTON, DC, 20005, US

(21) Appl. No.: 10/658,537

(22) Filed: Sep. 10, 2003

(30) Foreign Application Priority Data
Nov. 26, 2002 (JP) 2002-342108

(51) Int. Cl. H03D 1/00

(52) U.S. Cl. 375/340

(57) ABSTRACT

Radio apparatus is capable of quantitatively evaluating the improvement in the quality of received signals. A receiving circuit selects the evaluation mode in a mode selection circuit and transfers demodulated digital signals to an error generator. The digital signals are inverted in level by an Ex-OR gate circuit, using a predetermined timing supplied from a counter, to define an error condition, to transmit digital signals containing error data via a mode selection circuit to a error detector and a data register following thereto. The error data are periodically appended to the digital signals, which are in turn reproduced under a stable receiving state insusceptible of errors in order to quantitatively evaluate the extraneous sound suppressing effect of the receiving circuit.

### BACKGROUND OF THE INVENTION

1. Field of the Invention

The present invention relates to a receiver apparatus, advantageously applicable to a receiving circuit for radio communications.

2. Description of the Background Art

In equipment for receiving and processing signals, it has been thought desirable to raise the signal quality. For example, in a radio communications apparatus, such as a cellular phone, if received data are corrupted with errors, noise is produced as extraneous sound in the speech signals reproduced based on these data. For this reason, the radio communications apparatus demodulates received signals by a demodulating circuit and transfers the demodulated data to a receiving register and to an error detection circuit. The error detection circuit detects errors in the demodulated data and routes the error detection information to a codec circuit.

The codec circuit is responsive to the error detection information for the demodulated data, transferred from the receiving register to inhibit or suppress the extraneous sound, while reproducing the speech signals to output the reproduced signals. For inhibiting or suppressing the extraneous sound, the codec circuit limits the amplitude, or mutes the part, of the speech signals, corresponding to the error data, to annul the speech signals.

With the radio communications apparatus, to which that processing in the codec circuit is applied, it is required to make evaluation as to the extent of extraneous sound suppression in speech communications and the error correction performance in data communications. In order to make such evaluation, it is necessary for the error detection circuit to be provide with, instead of a simple detection of an error contained in one slot of data supplied, the error processing capability matching with that of the codec circuit and a supply of data which are so varied as to cause errors with a variety of numbers of bits. The error detection circuit is also required to change the position of error detection adaptively to actual cases. The position of error detection may, for example, be a data field or CRC (cyclic redundancy check) field. Correlation detection is executed in synchronous detection in a synchronous pattern field.

It should be noted that an error produced upon reception by a radio communications apparatus is dependent on the quality of received radio signals. Thus, when a radio communications apparatus receives a radio signal producing, e.g. a 1-bit error transmitted for evaluation, the apparatus fails, if affected by the environment of propagation, to evaluate the reception correctly. In the radio signal, it is extensively difficult to control for evaluation the positions of causing errors in the radio signals and to maintain the state of the radio signals. As a consequence, it is difficult with the radio communications apparatus to evaluate quantitatively the improvement in the quality of signal reception.

### SUMMARY OF THE INVENTION

It is an object of the present invention to provide a radio communications apparatus by means of which the defects inherent in the conventional technique may be overcome to render it possible to evaluate quantitatively the improvement in the quality of signal reception.

For accomplishing the above object, the present invention provides a receiver apparatus comprising a demodulator for demodulating received radio signals into digital signals, a mode selector for selecting either of a reproduction mode of reproducing the demodulated digital signals and an evaluation mode of evaluating the digital signals, and an error generator for inverting the level of the supplied digital signals for the evaluation mode at a predetermined timing to generate error data by the level inversion.

With the receiver apparatus according to the present invention, the evaluation mode is selected by the mode selector, the demodulated digital signals are supplied to the error generator and the digital signals so generated are inverted in signal level at a predetermined timing to define an error condition. In this manner, periodic error data are appended and reproduced, even under a stable signal receiving condition insusceptible to errors, in order to render it possible to quantitatively evaluate the effect of error suppression executed against errors or the error correction effect.

### BRIEF DESCRIPTION OF THE DRAWINGS

The objects and features of the present invention will become more apparent from consideration of the following detailed description taken in conjunction with the accompanying drawings in which:

FIG. 1 is a block diagram showing the schematic configuration of a receiving circuit employing a receiver apparatus according to the present invention;

FIG. 2 is a timing chart useful for understanding the timing of errors generated in the receiving circuit of FIG. 1;

FIGS. 3 and 4 are schematic block diagrams showing the configuration of alternative embodiments of the receiving circuit;

FIG. 5 is a timing chart useful for understanding the relation of the CRC timing signals relative to the digital signals and the error detection signals of the receiving circuit of FIG. 4;

FIGS. 6 and 7 are schematic block diagrams showing the configuration of further alternative embodiments of the receiving circuit;

FIG. 8 is a timing chart useful for understanding the relation of the data reception timing signals to digital signals or the error detection information supplied to the receiving circuit of FIG. 7; and

FIG. 9 is a schematic block diagram showing the configuration of a still further alternative embodiment of the receiving circuit.

### DESCRIPTION OF THE PREFERRED EMBODIMENTS

Referring to the accompanying drawings, certain preferred embodiments of the receiver apparatus of the present invention are described in detail. The parts and components not directly relevant to understanding of the invention are not shown nor described. In the following description, the signals are indicated by the reference numerals of connections on which the signals are conveyed.

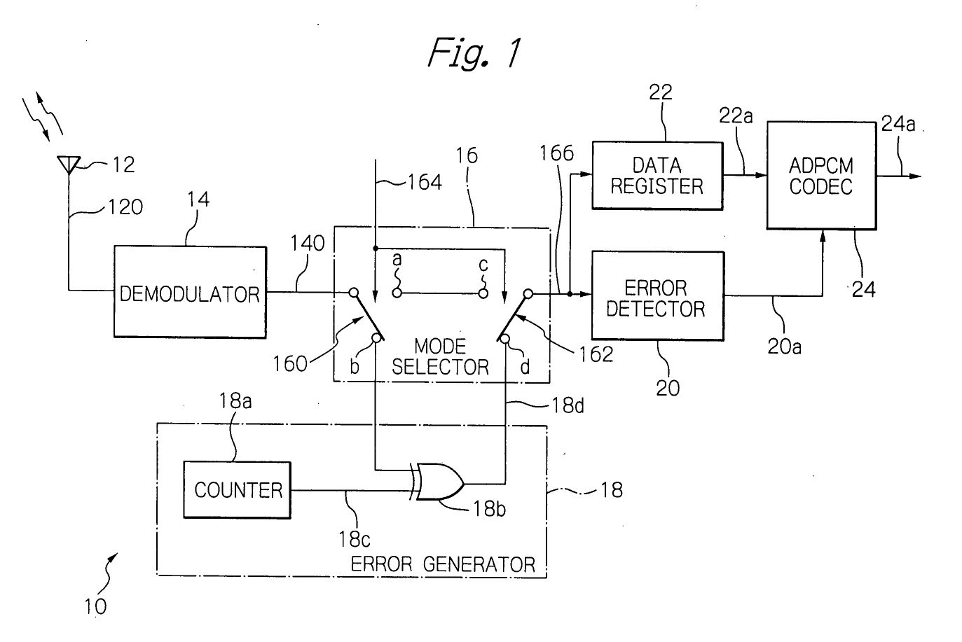

FIG. 1 shows schematically the configuration of an embodiment of the receiving circuit 10 included in a mobile station in the personal handyphone system (PHS), as an example of mobile telephone. The receiving circuit 10 includes an antenna 12, a demodulator 14, a mode selector 16, an error generator 18, an error detector 20, a data register 22 and an ADPCM (adaptive differential pulse code modulation) codec 24 interconnected as illustrated.

The antenna 12 is adapted for transducing the electromagnetic energy of a radio wave to electric power and vice versa in transmission/reception in communication with a base station, corresponding to a master device, by radio waves of a specified frequency. In reception, a received signal 120 corresponding to the transduced electric power is supplied to the demodulator 14.

Although not shown specifically, the demodulator 14 has the function of down-converting and demodulating the down-converted signal 120 to yield baseband signals, which are then digitized. The demodulator 14 outputs the so processed digital signals 140 to the mode selector 16.

The mode selector 16 includes a selector switch 160 for selecting the destination of digital signals 140 supplied and another selector switch 162 for selecting the source of the signal to be output from the mode selector 16. The one selector switch 160 has its terminals a and b for switching between the destination associated with the reproduction mode and the destination associated with the evaluation mode, respectively. The other selector switch 162 has its terminals c and d for selecting signals from a source associated with the reproduction mode and those from associated with the evaluation mode, respectively.

To this end, the terminals a and care coupled together. The selector switches 160 and 162 are in operation by a selection signal 164, supplied from a system controller, not shown, of the receiving circuit 10 so that the terminals a and c on one hand and the terminals b and d on the other hand will be selected simultaneously at a synchronized timing.

In particular, if the selector switch 160 selects the terminal b in the evaluation mode, the digital signals are supplied to the error generator 18. The selector switch 162 outputs digital signals from the error generator 18 via terminal d as an output signal of the mode selector 16. The mode selector 16 sends out a selected digital signal 166 to the error detector 20 and to the data register 22, without dependency on the mode.

If it is desired to simplify the configuration of the receiving circuit 10, the mode selector 16 may be omitted with an output and an input terminal of the circuit substituted for the selector switches 160 and 162, respectively.

The error generator 18 has the function of inverting the binary level of the digital signals 140, supplied thereto at a predetermined timing or period. The error generating method may not be limited to the above-described functions. For example, there is such a method in which a level on which an error is to be appended is fixed. As a configuration for implementing this function, the error generator 18 includes a counter 18a and an EXclusive OR (Ex-OR) gate circuit 18b. The counter 18b of the present embodiment carries up at a preset value and outputs an output signal upon the carrying-up. The counter 18a restarts cyclic counting to consequently output the output signal periodically. The counter 18a is thus adapted for generating a given error quantity.

The invention is not restricted to the provision of such a single counter. It is also possible to provide plural counters and to set a particular value to each of the counters, whereby it is possible to append more complicated errors.

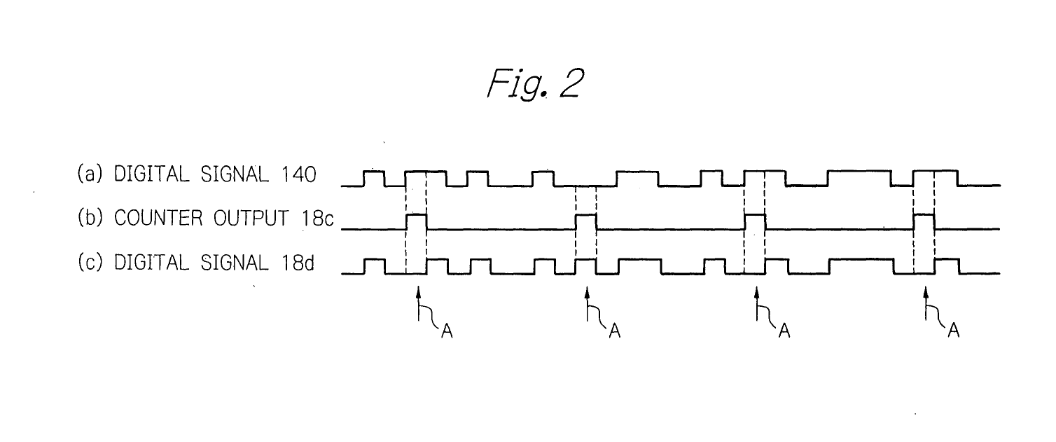

The Ex-OR gate circuit 18b has its one end supplied with the digital signals 140, as shown in FIG. 2, part(a), while having its other end supplied with an output signal 18c from the counter 18a, as shown in FIG. 2, part(b). Thus, the error generator 18 inverts the level of the digital signal 140 by the Ex-OR gate circuit 18b, as indicated by an arrow A in FIG. 2, part(c), to output a digital signal 18d at the terminal d, as indicated by arrow A in the part(c). Even though the receiving circuit 10 is in the normal radio environment such that no errors should be generated, the digital signal 18d comes to be corrupted with known errors, by the Ex-OR gate circuit 18b, at a predetermined timing or period. Thus, the mode selector 16 in the evaluation mode selects the digital signal 18d to transfer the signal as a digital signal 166 to the error detector 20 and to the data register 22.

In an application where the above-described, simplified configuration is applied to the receiving circuit 10, the error generator 18 may be provided externally. It should be noted that the error generator 18 is not limited to the above-described configuration, but may be structured such that the level is fixed to generate an error to be appended. Specifically, when the level is to be fixed at its HIGH level, the Ex-OR gate circuit 18b is replaced with a logical sum gate (OR) circuit. On the other hand, when the level is to be fixed at its LOW level, the Ex-OR gate circuit 18b is replaced with a logical product gate (AND) circuit.

Reverting to FIG. 1, the error detector 20 has the function of detecting an error contained in the input digital signal (data). The error detector 20 routes the detected error information 20a to the ADPCM codec 24.

The data register 22 temporarily holds digital signals 166, supplied thereto from the mode selector 16, as digital data. The data register 22 retains the data therein, taking account of time needed in error detection, and transfers the data 22a thus retained to the ADPCM codec 24.

The ADPCM codec 24 copes with, in the instant embodiment, the adaptive differential pulse code modulation employing at least one of the sequential adaptive quantization and the sequential adaptive prediction, and has, among the codec functions, the function of restoring the speech signals from supplied data composed only of residues. The ADPCM codec 24 ultimately effects D/A (digital-to-analog) conversion to output speech signals 24a. The ADPCM codec 24 of the embodiment also effects the processing of suppressing the extraneous sound in keeping with the supplied error information 20a. While transmitting or receiving data, the ADPCM codec 24 corrects errors at the locations of errors occurring in the data 22a, based on the error information 20a. Thus, if an output signal of the ADPCM codec 24 is measured, it is possible to quantitatively grasp to which extent correction has been achieved as compared to the given error.

The suppression of the extraneous sound includes limiting or muting the sound to be reproduced, but may not be limited thereto. For example, it is also possible to count the number of times the reproduced speech level has reached a predetermined limit and to mute, when the counted number of times exceeds a predetermined value, the reproduced speech for a predetermined time period. Methods for error correction is also not limited to the specific example described above.

The operation of the receiving circuit 10 is now briefly described. When the reproduction mode is selected, the digital signals 140 from the demodulator 14 are routed via the terminal a of the selector switch 160 and the terminal c of the selector switch 162 to the error detector 20 and to the data register 22. The ADPCM codec 24 effects decoding in keeping with the adaptive differential pulse code modulation on data 22a read out from the data register 22, while effecting error detection processing thereon.

When the mode selector 16 has selected the evaluation mode, the digital signals 140 are supplied via terminal b of the selector switch 160 to the error generator 18. The selector switch 162 is changed over to the terminal d, in synchronism with the selection of the terminal b, to output the digital signals 18d to the error detector 20. At this time, the error generator 18 appends an error of a given error quantity to the digital signals 18d. The digital signals 18d are supplied as the digital signals 166 to the error detector 20 and the data register 22. The ADPCM codec 24 effects decoding in keeping with the adaptive differential pulse code modulation on data 22a read out from the data register 22, while effecting error detection processing thereon.

This sort of evaluation is conducted in a distributed teleconferencing system, although belonging to the technical field different from the present invention, as disclosed by Japanese Patent Laid-Open Publication No. 226739/1995. In this distributed teleconferencing system, data changing means for formulating output data having data bits different from those of the input data or means for changing the cells of the input data are provided in a teleconferencing server, and pseudo-errors are artificially introduced into the data to effect strict qualitative evaluation of the quality of transmission. It is stated therein that a bit error introducing position generator is comprised of an 8-bit counter to determine the bit position where a bit error is to be introduced. In respect of inserting a bit error, however, the inversion of a specified bit is merely disclosed without teaching a specific technique for realizing the inversion.

In summary, the receiving circuit 10 of the embodiment executes, in a normal environment for radio waves in which an error is not liable to be incurred, the suppression of the extraneous sound or the correction of the errors with respect to a controlled, given quantity of errors, and measures the speech signals 24a from the codec 24 or the output signals pertinent to the data to determine the ability of the receiving circuit in suppressing the extraneous sound or in correcting the error. The suppression of the extraneous sound or error correction that can be achieved with the receiving circuit 10 may be quantitatively grasped and evaluated.

Alternative embodiments of the receiving circuit 10 will hereinafter be described. Since the alternative embodiments have the basic configuration in common with the embodiment of FIG. 1, the same reference numerals are used for denoting the similar parts or components, and the corresponding description is omitted for brevity.

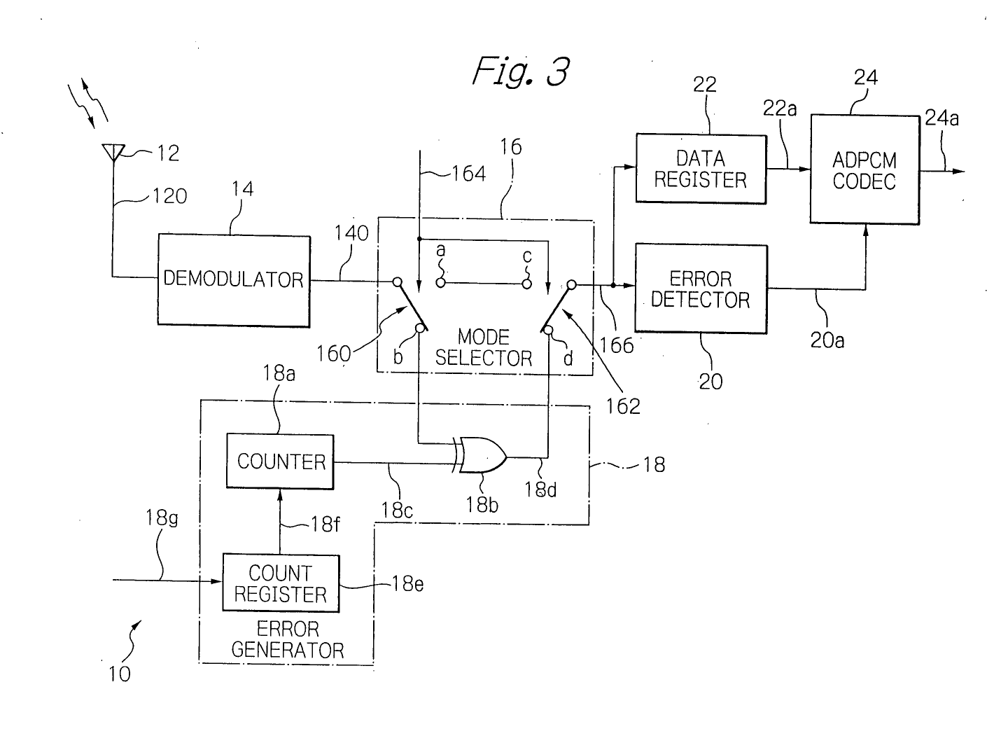

With reference to FIG. 3, an alternative embodiment of the receiving circuit 10 is the same as the previous embodiment except for a count register 18e added to the error generator 18 and a preset value 18f supplied to the counter 18a. To the counter 18a, a counter with a setting function may preferably be applicable in order to cope with a preset value 18f supplied thereto.

The count register 18e is small in circuit scale, having the function of storing its count. For supplying a preset value 18f to the counter 18a, a set value 18g is supplied from e.g. an external micro-computer to the count register 18e. By providing this count register 18e, it is possible to set the period of error generation to control the quantity of errors.

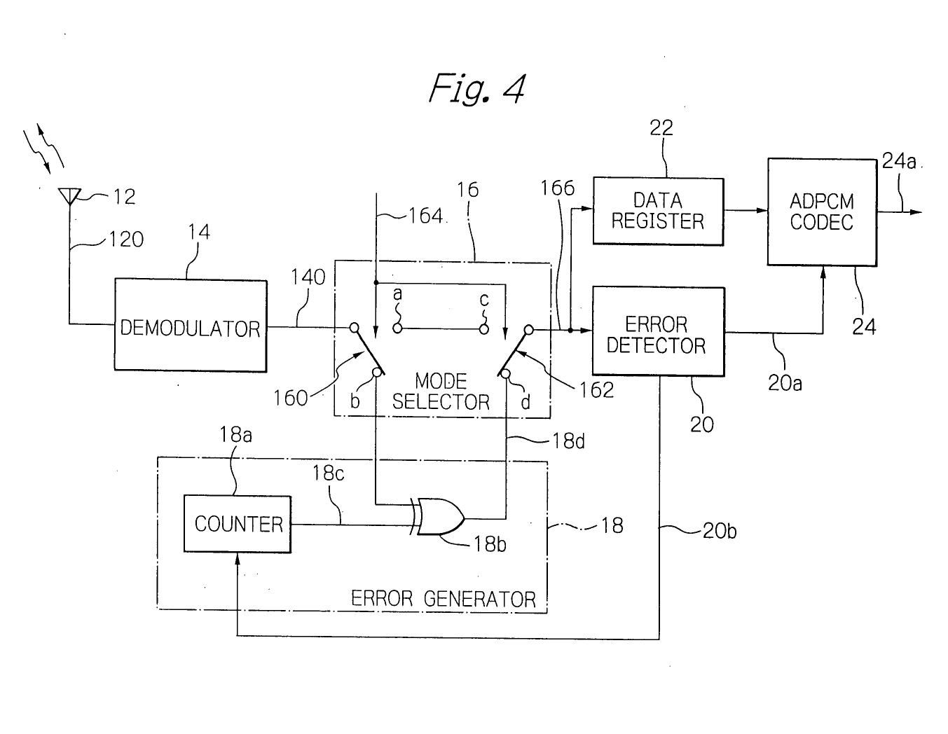

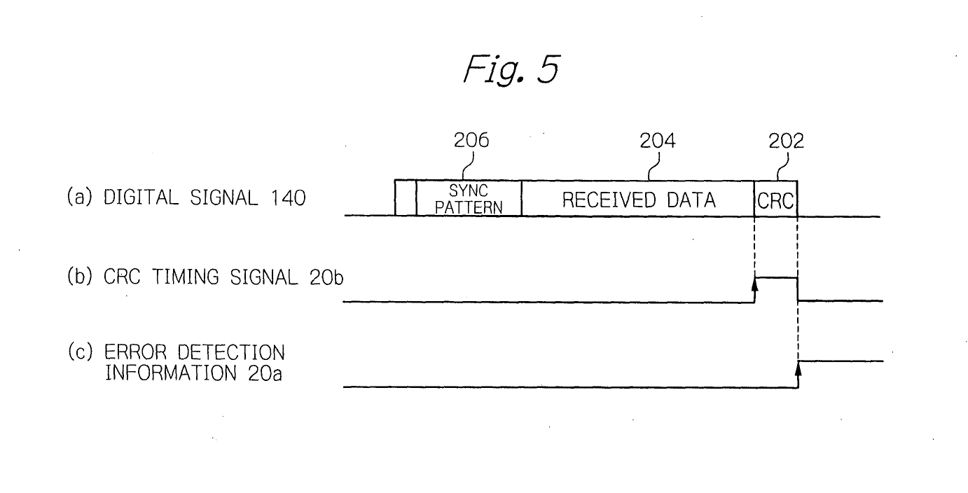

The receiving circuit 10 of a further alternative embodiment, shown in FIG. 4, is the same as the previous embodiment shown in FIG. 1 except that a CRC timing signal 20b defining the period of the CRC field is supplied from the error detector 20 to the counter 18a. The PHS system has its signal formats specified. If this format is taken into account, it can be grasped how the CRC field ranges in the digital signal 140. For example, as seen from FIG. 5, part (a), the CRC field 202 follows the received data field 204 after the synchronization word pattern (sync pattern) 206. That is, the start and end positions of the CRC field 202 can be determined. The error detector 20 exploits this relation to produce the CRC timing signal 20b, part(b), FIG. 4, included in the signals 166 supplied in the evaluation mode. The CRC timing signal 20b prescribes the operating period of the counter 18a.

The counter 18a is supplied with the CRC timing signal 20b to commence its counting operation. The counter 18a sends out the output signal 18c to the Ex-OR gate circuit 18b during the period of the CRC field 202. The Ex-OR gate circuit 18b appends an error bit to the CRC filed 202 of the digital signal 140 to output the digital signals 18d. The mode selector 16 transfers the digital signal 18d as a digital signal 166 to the error detector 20.

The error detector 20 detects errors in received data 204 lying between the sync pattern 206 and the CRC field 202. It is assumed that the received data 204 is free of errors. The error detector 20 generates the CRC from the received data 204 for comparison to the data in the CRC field 202. If the results from the comparison shows non-coincidence, the error detector 20 then provides the ADPCM codec 24 with the error detection information 20a, FIG. 5, part (c), indicating the fact of the error detection.

In this manner, the alternative embodiment allows an error to be appended to a specified range in slot data. Thus, the occurrence of an error in the CRC field 202 can be quantitatively determined, using the digital signal containing the given error presumed to have occurred in the data received on radio transmission, thus allowing evaluation of the effect of suppressing the extraneous noise in the reproduced speech.

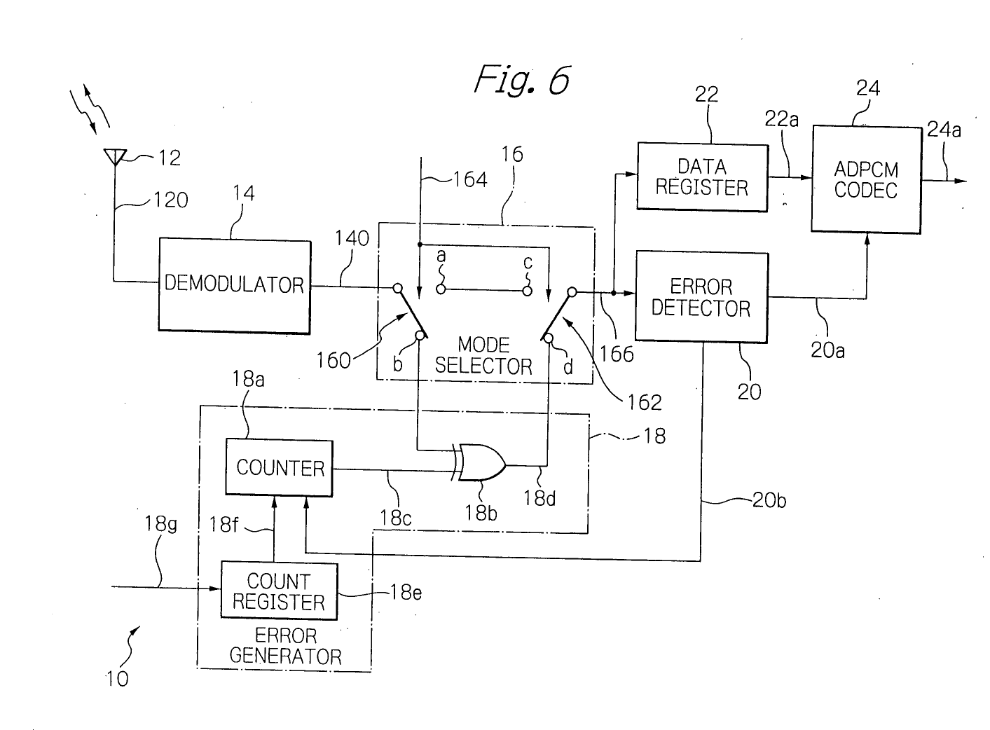

With a still further alternative embodiment shown in FIG. 6, the receiving circuit 10 is comprised of the combination of the above-described, two alternative embodiments. Thus, the receiving circuit 10 of the still further embodiment is able to set a preset value 18f supplied to the CRC field for error detection. The illustrative embodiment is superior to the embodiment shown in FIG. 4 in the freedom to set the error condition.

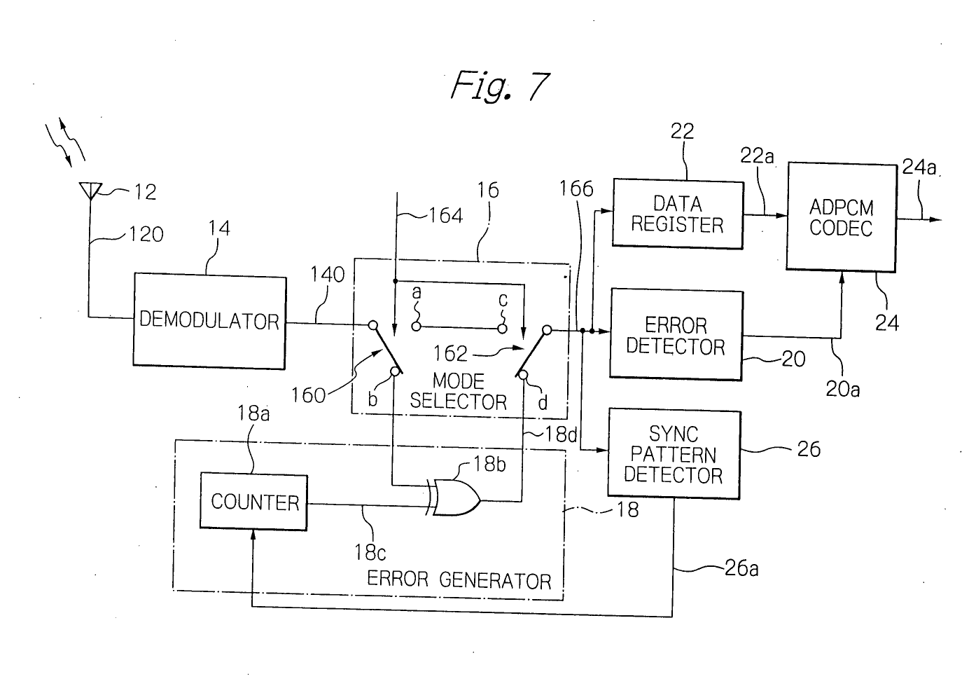

The receiving circuit 10 of another alternative embodiment shown in FIG. 7 is the same as the previous embodiment shown in FIG. 1 except for a sync pattern detector 26 is added together with circuitry associated therewith. This sync pattern detector 26 detects the time period of the sync pattern field specified by the sync word. As understood from FIG. 5, for example, subsequent to the detection of sync pattern 206, the field 204 of the received data appears over a predetermined number of bits of data string. The sync pattern detector 26 is adapted, utilizing that feature, to provide the counter 18a with a data reception timing signal 26a. This accounts for the difference of the instant alternative embodiment from the previous embodiments.

The sync pattern detector 26 compares a preset sync word to the supplied digital signal 166 to verify whether or not detection is possible depending on complete coincidence of patterns. If the synchronization is once determined, the sync pattern detector 26 is easily able to find out the start of the sync pattern 206. Because, in the case of the PHS, the end position, and hence the field, of the sync pattern 206 are dependent on whether the slot used for detection is a physical slot for control or a physical slot for communication, and the sync words for the former and for the latter have 32 bits and 16 bits, respectively. In addition, since the data field 204 as from the sync pattern 206 is prescribed to be 108 bits or 180 bits, depending on the slot type, as described previously, the sync pattern detector 26 is able to output a data reception timing signal 26a, defining the data field 204.

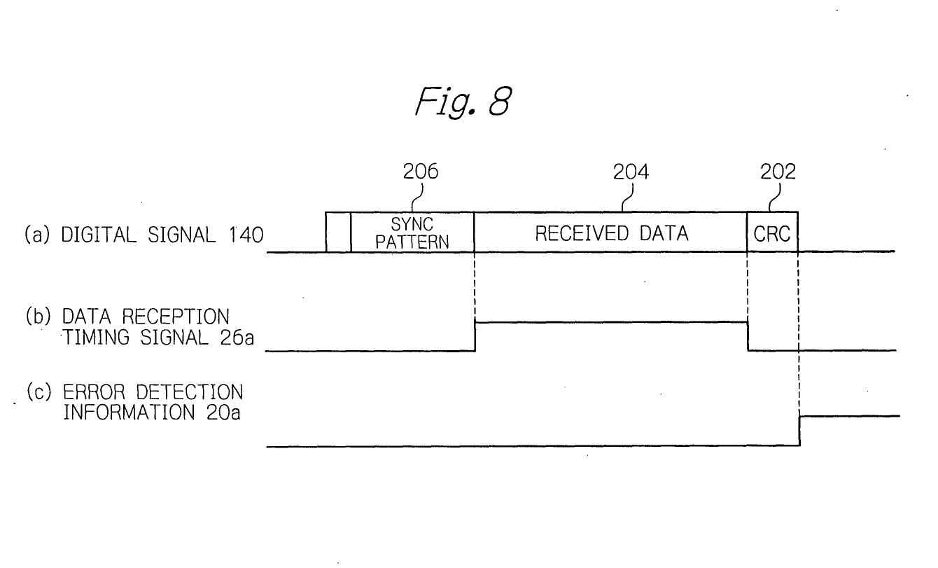

The digital signal 140, thus prescribed, is supplied with a slot containing a sync pattern 206, received data 204 and the CRC 202 as a unit, as shown in FIG. 8, part (a). If the sync pattern 206 is detected by the sync pattern detection processing by the sync pattern detector 26, and the sync pattern 206 has come to its close, the sync pattern detector 26 then shifts the data reception timing signal 26a to its HIGH level to provide it to the counter 18a, over the field of the received signal 204, as shown in part (b). On receipt of the data reception timing signal 26a, the counter 18a is set to its operating state and continues the counting during the HIGH signal level period.

The counter 18a feeds the Ex-OR gate circuit 18b with a pulse signal 18c defining a timing at which error bits are generated at a preset period in the received data field 206. The Ex-OR gate circuit 18b is responsive to the supplied pulse signal 18c to append an error bit. The error detector 20 is supplied with an input signal 166 to execute the processing of error detection thereon. If the error detector 20 detects an error, the detector 20 outputs the error detection information 20a shown in FIG. 8, part (c). In this example, the receiving circuit 10 is in an environment of the radio waves insusceptible to error. No error is contained in the CRC field 202, such that correct data is supplied.

Under these premises, the receiving circuit 10 sends out the given error quantity and detects errors to measure the reproduced speech or data output by the ADPCM codec 24. The receiving circuit 10 can thus quantitatively check and evaluate the effect of suppressing extraneous sound in the reproduced speech and the ability of data correction against errors in the received data.

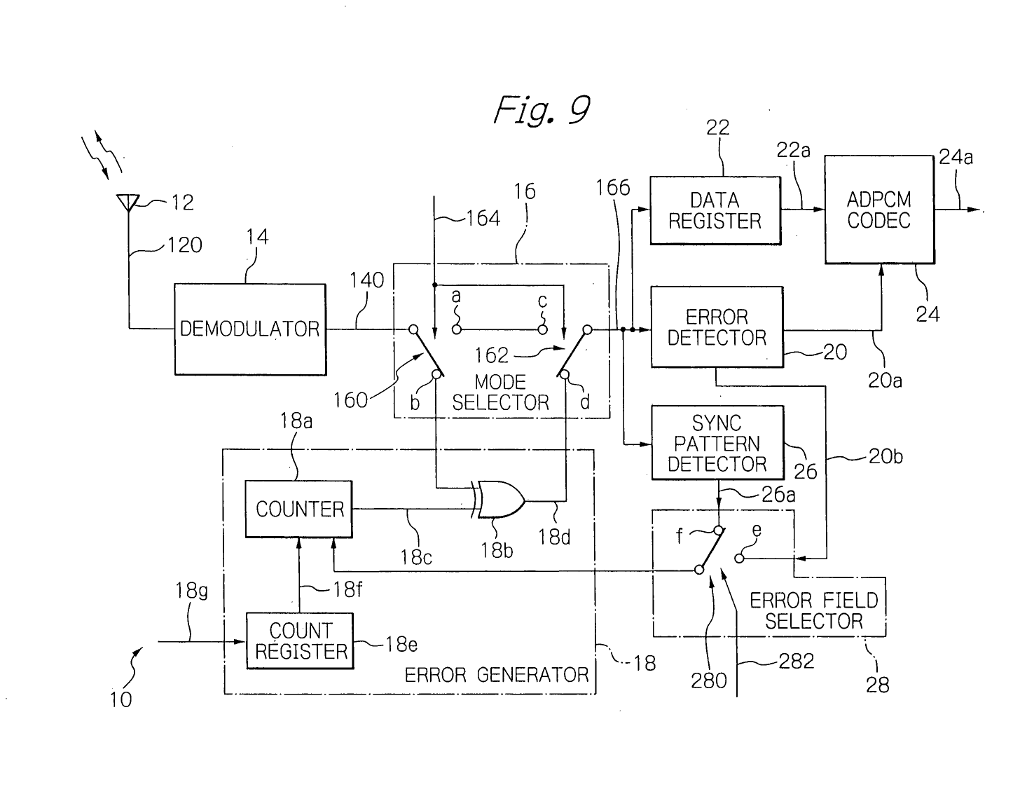

With reference to FIG. 9, the receiving circuit 10 of still another alternative embodiment is the same as the embodiment shown in FIG. 6 except that an error field selector 28 is provided and the sync pattern detector 26 is added, as with the embodiment shown in FIG. 7, together with circuitry associated. The error field selector 28 includes a selector switch 280 interconnected as illustrated. The selector switch 280 has its terminal e and f supplied with the CRC timing signal 20b and the data reception timing signal 26a, respectively. The selector switch 280 has its control terminal supplied with a selection signal 282 from a system controller, not shown. The selector switch 280 is responsive to the selection signal 282 to send out one of the above timing signals to the counter 18a.

In the operation of the receiving circuit 10 of the embodiment, the quantity of error addition also can be controlled as described with reference to the embodiment shown in FIG. 1 to enable the evaluation of the extraneous sound suppressing effect in the reproduced speech against different error quantities. The receiving circuit 10, including the error field selector 28 for selecting the timing signal supplied to the counter 18a, enables errors to be easily appended responsive to the selection of the error field.

With the embodiment, the error is appended in a timing conforming to a specific field to effect error detection and, responsive to this error detection, the reproduced speech or data output by the ADPCM codec 24 is measured to make quantitative check and evaluation of the extraneous sound suppressing effect or the data correction ability in the reproduced sound against errors in the CRC and the received data.

Although the above description has been made with reference to the application of PHS, the present invention is not limited to this particular application. However, the receiver apparatus of the present invention may, of course, be applied to cellular phones or a receiver apparatus in which the format of the data structure is prescribed.

With the illustrative embodiments described above, an error bit may be appended to the received digital signals, at a predetermined timing or periodically, to the received digital signals, under a stabilized receiving condition in which errors are not liable to be produced, in order to enable quantitative evaluation of the extraneous sound suppressing effect or the data correction ability attendant on reproduction of digital signals.

Moreover, by enabling a preset value to be set, the quantity of error appendage can be controlled to evaluate the quality of the reproduced signals against different error quantities.

By designating the range of error appendage, for example, by limitatively designating a field, such as the CRC or received data field, as the range of error appendage to append errors, it is possible to establish the quantitative evaluation for a specific range. If a preset value is appropriately set, evaluation may be made for different error quantities.

By providing the error field selector 28 in the receiving circuit 10, the counter 18a can be activated only during the period corresponding to the selected field to cope with the demand for evaluation.

The entire disclosure of Japanese patent application No. 2002-342108 filed on Nov. 26, 2002, including the specification, claims, accompanying drawings and abstract of the disclosure is incorporated herein by reference in its entirety.

While the present invention has been described with reference to the particular illustrative embodiments, it is not to be restricted by the embodiments. It is to be appreciated that those skilled in the art can change or modify the embodiments without departing from the scope and spirit of the present invention.

What is claimed is:

1. A receiver apparatus comprising:
a demodulator for demodulating received radio signals into digital signals;
a mode selector for selecting either of a reproduction mode of reproducing the digital signals and an evaluation mode of evaluating the digital signals; and
an error generator for inverting a level of the digital signals for the evaluation mode at a predetermined timing to generate error data.

2. The apparatus in accordance with claim 1, wherein said mode selector comprises:
a first selector for selecting a destination of the digital signals; and
a second selector for selecting a source from either of said first selector and said error generator;
said first and second selectors synchronously selecting a same mode side.

3. The apparatus in accordance with claim 2, wherein said error generator comprises:
a pulse outputting circuit for outputting pulse signals at the predetermined timing; and
an inverter for inverting the level of the digital signals responsive to a transmission of the pulse signals.

4. The apparatus in accordance with claim 3, wherein said error generator comprises a preset value holding circuit which has a preset value defining a transmission timing of the pulse signals set from outside said apparatus to hold the preset value to supply the preset value to said pulse outputting circuit.

5. The apparatus in accordance with claim 1, further comprising an error detector interconnected to said mode selector for detecting an error contained in the digital signals;
said error detector supplying said pulse outputting circuit with an output timing defining a field of the digital signal in which check data for received data are held.

6. The apparatus in accordance with claim 2, further comprising an error detector interconnected to said mode selector for detecting an error contained in the digital signals;
said error detector supplying said pulse outputting circuit with an output timing defining a field of the digital signal in which check data for received data are held.

7. The apparatus in accordance with claim 3, further comprising an error detector interconnected to said mode selector for detecting an error contained in the digital signals;
said error detector supplying said pulse outputting circuit with an output timing defining a field of the digital signal in which check data for received data are held.

8. The apparatus in accordance with claim 4, further comprising an error detector interconnected to said mode selector for detecting an error contained in the digital signals;
said error detector supplying said pulse outputting circuit with an output timing defining a field of the digital signal in which check data for received data are held.

9. The apparatus in accordance with claim 1, further comprising a sync pattern detector interconnected to said mode selector for detecting a sync pattern contained in the digital signals;
said synchronous pattern detector supplying said pulse outputting circuit with an output timing defining a field of received data which follows the sync pattern and holds check data.

10. The apparatus in accordance with claim 2, further comprising a sync pattern detector interconnected to said mode selector for detecting a sync pattern contained in the digital signals;
said synchronous pattern detector supplying said pulse outputting circuit with an output timing defining a field of received data which follows the sync pattern and holds check data.

11. The apparatus in accordance with claim 3, further comprising a sync pattern detector interconnected to said mode selector for detecting a sync pattern contained in the digital signals;
said synchronous pattern detector supplying said pulse outputting circuit with an output timing defining a field of received data which follows the sync pattern and holds check data.

12. The apparatus in accordance with claim 4, further comprising a sync pattern detector interconnected to said mode selector for detecting a sync pattern contained in the digital signals;
said synchronous pattern detector supplying said pulse outputting circuit with an output timing defining a field of received data which follows the sync pattern and holds check data.

13. The apparatus in accordance with claim 5, further comprising a sync pattern detector interconnected to said mode selector for detecting a sync pattern contained in the digital signals;
said synchronous pattern detector supplying said pulse outputting circuit with an output timing defining a field of received data which follows the sync pattern and holds check data.

14. The apparatus in accordance with claim 9, further comprising:
an error detector for detecting an error contained in the digital signals; and
a timing selector for selecting an output timing supplied from either of said error detector and said sync pattern detector.

15. The apparatus in accordance with claim 10, further comprising:
an error detector for detecting an error contained in the digital signals; and
a timing selector for selecting an output timing supplied from either of said error detector and said sync pattern detector.

16. The apparatus in accordance with claim 11, further comprising:
an error detector for detecting an error contained in the digital signals; and
a timing selector for selecting an output timing supplied from either of said error detector and said sync pattern detector.

17. The apparatus in accordance with claim 12, further comprising:
an error detector for detecting an error contained in the digital signals; and
a timing selector for selecting an output timing supplied from either of said error detector and said sync pattern detector.

18. The apparatus in accordance with claim 13, further comprising:
an error detector for detecting an error contained in the digital signals; and
a timing selector for selecting an output timing supplied from either of said error detector and said sync pattern detector.
